(19) United States
(12) Patent Application Publication
(10) Pub. No.: US 2009/0142891 A1
(43) Pub. Date: Jun. 4, 2009

(54) MASKLESS STRESS MEMORIZATION TECHNIQUE FOR CMOS DEVICES

(75) Inventors: Young-Hee Kim, Yorktown Heights, NY (US); Jeffrey W. Sleight, Ridgefield, CT (US); Huiming Bu, Millwood, NY (US); Rick Carter, Hopewell Junction, NY (US); Mike Hargrove, Clinton Corners, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: International Business Machines Corporation, Armonk, NY (US)

(21) Appl. No.: 11/948,849

(22) Filed: Nov. 30, 2007

(51) Int. Cl. H01L 21/8238

(52) U.S. Cl. 438/199; 257/E21.632

(57) ABSTRACT

In one embodiment, the present invention provides a method of manufacturing a semiconducting device that includes providing a silicon containing substrate having PFET device and NFET device, wherein the NFET device includes an amorphous silicon containing region; depositing a tensile strain silicon nitride layer atop the NFET device and the PFET device, wherein the silicon nitride tensile strain layer induces a tensile strain in a channel of the NFET device region; annealing to crystallize the amorphous silicon containing region, wherein the tensile strain silicon nitride layer positioned atop the PFET device confines oxygen within a channel positioned within the silicon containing substrate underlying the PFET device, wherein the oxygen within the channel shifts a threshold voltage of the PFET device towards a valence band of silicon of the silicon containing substrate; and removing the tensile strain silicon nitride layer.

### FIELD OF THE INVENTION

The present invention generally relates to microelectronics. In one embodiment, the present invention relates to a complementary metal oxide semiconductor (CMOS) device, in which at least one field effect transistor of the device has a strained channel.

### BACKGROUND OF THE INVENTION

Semiconductor devices are used in a large number of electronic devices such as computers, cell phones and others. One of the goals of the semiconductor industry is to continue shrinking the size and increasing the speed of individual devices. Smaller devices can operate at higher speeds, since the physical distance between components is smaller. In addition, higher conductivity materials such as copper are replacing lower conductivity materials, such as aluminum. One other challenge is to increase the mobility of semiconductor carriers, such as electrons and holes.

One technique to improve transistor performance is to provide a stress layer over the transistor. Variants of stress layers can be used for mobility and performance boost of devices. For example, stress can be provided by a contact etch stop layer (CESL), a single stress-inducing layer, dual stress-inducing layers, stress memory transfer layers, and/or STI liners. Most of these techniques use nitride layers to provide tensile and compressive stresses. In other applications, oxide layers can be used.

### SUMMARY OF THE INVENTION

The present invention, in one aspect provides a method of forming a CMOS device that includes at least one NFET device having a tensile strained channel and at least one PFET having a threshold voltage that is reduced by oxygen that is present in the channel region of the PFET devices. In one embodiment, the inventive method includes:

providing a silicon containing substrate having a first device region including at least one PFET device and a second device region including at least one NFET device, wherein the at least one NFET device includes an amorphous silicon containing region;
forming a tensile strain silicon nitride layer atop the at least one NFET device and the at least one PFET device, wherein the tensile strain silicon nitride layer induces a tensile strain in a channel of the at least one NFET device;
annealing to crystallize the amorphous silicon containing region, wherein the tensile strain silicon nitride layer positioned atop the at least one PFET device confines oxygen within a channel positioned in the silicon containing substrate underlying the at least one PFET device, wherein the oxygen within the channel shifts a threshold voltage of the at least one PFET device towards a valence band of silicon of the silicon containing substrate; and
removing the tensile strain silicon nitride layer.

In another aspect of the present invention, a method of forming a CMOS device is provided that includes at least one NFET device having a tensile strained channel and at least one PFET having a threshold voltage that ranges from about 0.2V to about 0.45V. In one embodiment, the method includes:

providing a silicon containing substrate having a first device region including at least one PFET device and a second device region including at least one NFET device, wherein the at least one NFET device includes an amorphous silicon containing region;
forming a tensile strain layer atop the at least one NFET device and the at least one PFET device, wherein the tensile strain layer induces a tensile strain in a channel of the at least one NFET device;
annealing to crystallize the amorphous silicon containing region, wherein the tensile strain layer positioned atop the at least one PFET device confines oxygen in a channel positioned within the silicon containing substrate underlying the at least one PFET device, wherein a threshold voltage of the at least one PFET device ranges from about 0.2 V to about 0.45V; and
removing the tensile strain layer.

### BRIEF DESCRIPTION OF THE DRAWINGS

The following detailed description, given by way of example and not intended to limit the invention solely thereto, will best be appreciated in conjunction with the accompanying drawings, wherein like reference numerals denote like elements and parts, in which:

FIGS. 1-4 depict side cross sectional views of a method for forming a semiconducting device having NFET devices that include tensile strained channel regions, and PFET devices having a threshold voltage that is lowered by the entrapment of oxygen within the channel of the PFET, in accordance with one embodiment of the present invention.

### DETAILED DESCRIPTION OF THE INVENTION

Detailed embodiments of the present invention are disclosed herein; however, it is to be understood that the disclosed embodiments are merely illustrative of the invention that may be embodied in various forms. In addition, each of the examples given in connection with the various embodiments of the invention are intended to be illustrative, and not restrictive. Further, the figures are not necessarily to scale, some features may be exaggerated to show details of particular components. Therefore, specific structural and functional details disclosed herein are not to be interpreted as limiting, but merely as a representative basis for teaching one skilled in the art to variously employ the present invention.

The embodiments of the present invention relate to novel methods for forming metal oxide semiconductor field effect transistors (MOSFET) having a tensile strained NFET channel. When describing the methods, the following terms have the following meanings, unless otherwise indicated.

As used herein, “semiconductor device” refers to an intrinsic semiconductor material that has been doped, that is, into which a doping agent has been introduced, giving it different electrical properties than the intrinsic semiconductor. Doping involves adding dopant atoms to an intrinsic semiconductor, which changes the electron and hole carrier concentrations of the intrinsic semiconductor at thermal equilibrium. In intrinsic semiconductors, the valence band and the conduction band are separated by the energy gap that may be as great as about 1.2 eV.

As used herein, a “PFET” refers to a semiconductor device created by the addition of trivalent impurities such as boron, aluminum or gallium to an intrinsic Si substrate to creates deficiencies of valence electrons.

As used herein, an “NFET” refers to a semiconductor device created by the addition of pentavalent impurities such as antimony, arsenic or phosphorous that contributes free electrons to an intrinsic Si substrate.

As used herein, the term “amorphous” denotes a non-crystalline solid having no periodicity and long-range order, i.e., lacking a specific crystal structure.

As used herein, the terms “crystalline” or “crystallize” means a solid arranged in fixed geometric patterns or lattices or forming a solid arranged in fixed geometric patterns or lattices.

A “gate structure” means a structure used to control output current (i.e., flow of carriers in the channel) of a semiconducting device, such as a field effect transistor (FET).

As used herein, the term “dielectric” denote a non-metallic material having insulating properties.

As used herein, “insulating” denotes a room temperature conductivity of less than about 10⁻¹⁰(Ω-m)⁻¹.

As used herein, “conductive” denotes a room temperature conductivity of greater than about 10⁻⁸(Ω-m)⁻¹.

As used herein, “threshold voltage” is the lowest attainable voltage that will turn on an transistor.

As used herein, the term “channel” is the region between the source and drain of a metal oxide semiconductor transistor that becomes conductive when the transistor is turned on.

As used herein, the term “tensile strain layer” is a uniformly deposited Si₃N₄ layer of thickness ranging from 10 nm to 100 nm with inherent tensile strain in the gigapascal (Gp) range due to the N—H bonding properties of the material.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the invention, as it is oriented in the drawing figures.

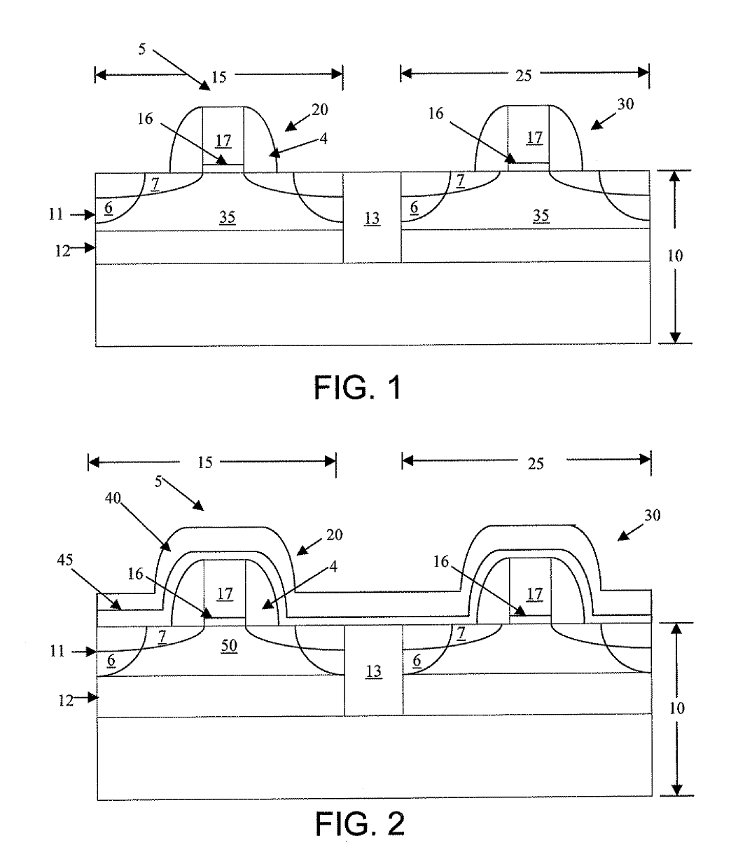

FIG. 1 depicts one embodiment of a silicon containing substrate 10 having a first device region 15 including at least one NFET device 20 and a second device region 25 including at least one PFET device 30, wherein the at least one NFET device 20 includes an amorphous silicon containing region 35. In one embodiment, the amorphous silicon containing region 35 is present in both the first device region 15 and the second device region 25.

The substrate 10 may be any silicon containing substrate including, but not limited to: Si, bulk Si, single crystal Si, polycrystalline Si, SiGe, amorphous Si, silicon-on-insulator substrates (SOI), SiGe-on-insulator (SOI), strained-silicon-on-insulator, annealed poly Si, and poly Si line structures. In one embodiment, when the substrate 10 is a silicon-on-insulator (SOI) or SiGe-on-insulator (SGOI) substrate, as depicted in FIG. 1, the thickness of the semiconducting Si-containing layer 11 atop the buried insulating layer 12 can have a thickness on the order of about 10 nm or greater. In one embodiment, the SOI or SGOI substrate may be fabricated using a thermal bonding process, or alternatively be fabricated by an ion implantation process, such as separation by ion implantation of oxygen (SIMOX).

In one embodiment, the substrate 10 includes an isolation region 13 separating the semiconducting silicon-containing layer 11 of the first device region 15 from the second device region 20. In one embodiment, the isolation region 13 is formed by etching a trench in the substrate 10 utilizing a dry etching process, such as reactive-ion etching (RIE) or plasma etching, and then filling the trench with an insulating material, such as an oxide. In one embodiment, the trench may be filled using a deposition method, such as chemical vapor deposition.

In one embodiment, the first device region 15 includes at least one NFET device 20 and the second device region 25 includes at least one PFET device 30. In one embodiment, each NFET and PFET devices 20, 30 includes a gate structure 5, wherein the gates structures 5 are formed atop the substrate 10 utilizing deposition, lithography, and etching. In one embodiment, a gate stack is first provided atop the substrate 10 by depositing a gate dielectric layer and then a gate conductor layer using forming methods, such as chemical vapor deposition and/or thermal growth. Thereafter, the gate stack is patterned and etched to provide the gate structure 5, wherein each gate structure 5 includes a gate dielectric 16 and a gate conductor 17.

In one embodiment, the gate dielectric 16 is an oxide material and is greater than about 0.8 nm thick. In another embodiment, the gate dielectric 16 may have a thickness ranging from about 1.0 nm to about 6.0 nm. In one embodiment, the gate dielectric 16 is a high-k gate dielectric comprised of an insulating material having a dielectric constant of greater than about 4.0, preferably greater than 7.0. More specifically, the high-k gate dielectric employed in the present invention may include, but not limited to: an oxide, nitride, oxynitride and/or silicate including metal silicates and nitrided metal silicates. In one embodiment, it is preferred that the gate dielectric 16 is comprised of an oxide such as, for example, HfO₂, ZrO₂, Al₂O₃, TiO₂, La₂O₃, SrTiO₃, LaAlO₃, Y₂O₃ and mixtures thereof. Hafnium containing high-k dielectrics include HfO₂, hafnium silicate and hafnium silicon oxynitride.

The gate conductor 17 may be comprised of polysilicon and/or a metal. The gate conductor 17 is formed atop the gate dielectric 16 utilizing a deposition process, such as CVD and/or sputtering. In one embodiment, the gate conductor 17 comprises doped polysilicon. The polysilicon dopant can be elements from group III-A or a group V-A of the Periodic Table of Elements. The dopant may be introduced during deposition of the gate conductor layer or following subsequent patterning and etching of the gate conductor 17.

In one embodiment, following the formation of the gate structure 5, a thin dielectric spacer 4 is formed abutting and protecting the gate structure sidewalls. In one embodiment, the thin dielectric spacer 4 is an oxide, such as SiO₂. The thin dielectric spacer 4 width W1 ranges from about 1 nm to about 20 nm. Forming processes such as deposition or thermal growing may produce the thin dielectric spacer 4. In a following process step, source/drain extension regions 7 may be formed in the substrate 10 and partially extend under the gate structure 5. Source/drain extension regions 7 are formed via ion implantation. PFET devices are produced within Si-containing substrates by doping the source/drain extension regions 7 with elements from group III-A of the Periodic Table of Elements. NFET devices are produced within Si-containing substrates by doping the source/drain extension regions 7 with elements from group V-A of the Periodic Table of Elements. Following source/drain extension region 7 implants, a disposable spacer (not shown) is formed abutting the exterior surface of the thin sidewall spacer 4. Following disposable spacer formation, a higher energy ion implant is conducted to form deep source/drain regions 6. These implants are conducted at a higher energy and higher concentration of dopant than the source/drain extension region 7 implant. The deep source/drain regions 6 are typically doped with a dopant type consistent with the source/drain extension regions 7. In one embodiment, following deep source/drain region 6 formation, the disposable spacers are removed, and the source/drain region 6 and gate region 5 are activated by activation annealing. Activation anneal may be conducted at a temperature ranging from about 850° C. to about 1350° C.

Still referring to FIG. 1, in a following process step, the amorphous Si containing region 35 is formed in the substrate 10 underlying at least the NFET device 20. In one embodiment, the amorphous Si containing region 35 is formed underlying the NFET and PFET devices 20, 30. In one embodiment, the amorphous layer Si containing region 35 is formed by disrupting a portion of the crystalline lattice of the substrate 10. In one embodiment, this process, which may be referred to as amorphization, is accomplished using an ion implant that may include germanium at about 1E14 to 1E15 cm², at about 20 keV to 40 keV. In another embodiment, amorphization of the substrate 10 is accomplished using an ion implant that includes xenon at about 1E14 to 1E15 cm², at about 20 keV to 40 keV. In one embodiment, the amorphous Si containing layer 35 is present at a depth ranging from 10 nm to about 70 nm, as measured from the upper surface of the substrate 10. In one embodiment, the amorphous Si containing region 35 has a thickness ranging from about 20 nm to 50 nm. In one embodiment, prior to implantation to form the amorphous Si containing region 35, the NFET and PFET devices 20, 30 are protected by a protective layer (not shown) that is deposited atop the devices. The protective layer may be composed of an oxide, nitride or oxynitride material.

FIG. 2 depicts forming a tensile strain layer 40 atop at least one NFET device 20 and at least one PFET device 30, wherein the tensile strain layer 40 induces a tensile strain in a channel 50 of at least one NFET device 20, in accordance with one embodiment of the present invention. In one embodiment, the tensile strain layer 40 may be a nitride, an oxide, a doped oxide, such as boron phosphate silicate glass, Al₂O₃, HfO₂, ZrO₂, HfSiO, or any combination thereof. In one embodiment, the tensile strain layer 40 may have a thickness ranging from about 10 nm to about 500 nm. In another embodiment, the tensile strain layer 40 has a thickness ranging from about 50 nm to about 450 nm. In one embodiment, the tensile strain layer 40 may be deposited by plasma enhanced chemical vapor deposition (PECVD) or rapid thermal chemical vapor deposition (RTCVD).

In one embodiment when the tensile strain liner 40 is composed of a nitride, such as Si₃N₄, the process conditions of the deposition process of the tensile strain liner 40 are selected to provide an intrinsic tensile strain within the deposited layer. For example, plasma enhanced chemical vapor deposition (PECVD) can provide nitride stress inducing liners having an intrinsic tensile strain. The stress state of the nitride stress including liners deposited by PECVD can be controlled by changing the deposition conditions to alter the reaction rate within the deposition chamber. More specifically, the stress state of the deposited nitride strain inducing liner may be set by changing the deposition conditions such as: SiH₄/N₂/He gas flow rate, pressure, RF power, and electrode gap.

In another example, rapid thermal chemical vapor deposition (RTCVD) can provide nitride tensile strain liners having an internal tensile strain. In one embodiment, the magnitude of the internal tensile strain produced within the nitride tensile strain liner deposited by RTCVD can be controlled by changing the deposition conditions. More specifically, the magnitude of the tensile strain within the nitride tensile strain liner may be set by changing deposition conditions, such as: precursor composition, precursor flow rate and temperature.

In one embodiment, when the tensile strain layer 40 is composed of Si₃N₄ having a thickness ranging from about 10 nm to about 70 nm and deposited by PECVD to provide a tensile strain that is produced in at least the channel region 50 of the NFET devices 20 that may range from about 0.5 Gp to about 1.0 Gp. In one embodiment, prior to the formation of the tensile strain layer 40, a conformal liner 45 is formed atop the substrate 10 and the gate structures 5. In one embodiment, the conformal liner 45 is a dielectric material, such as an oxide, nitride or oxynitride. The conformal liner 45 may be deposited by chemical vapor deposition or may be formed using a thermal growth process. In one embodiment, the conformal liner 45 may have a thickness ranging from about 8 nm to about 20 nm. In one embodiment, the conformal liner 45 may be an oxide, such as SiO₂, thermally grown to a thickness on the order of 10 Å.

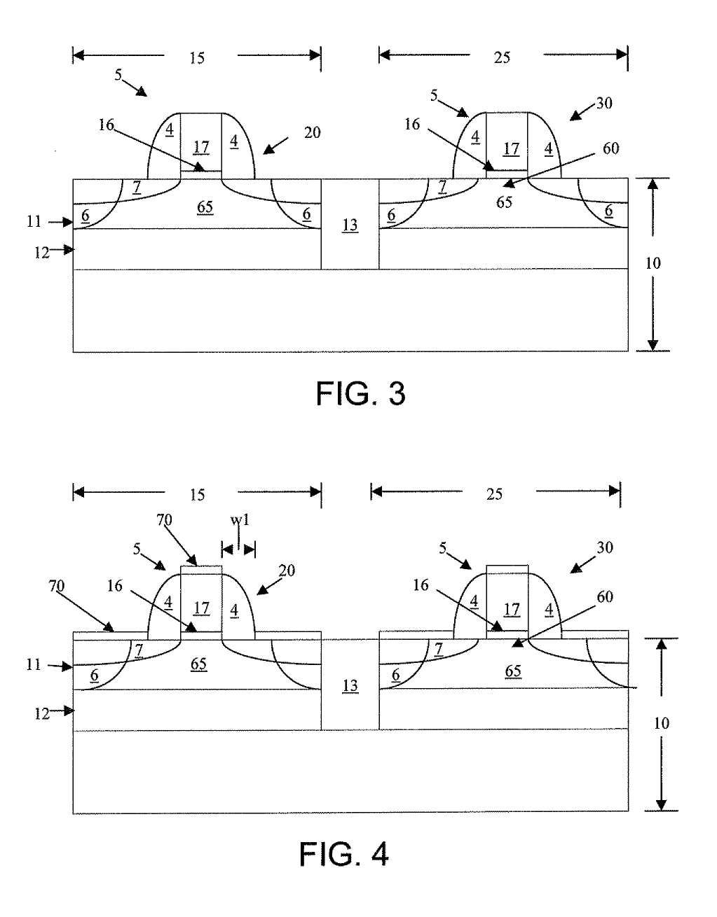

FIG. 3 depicts one embodiment of annealing to crystallize the amorphous silicon containing region 35, wherein the tensile strain layer 40 positioned atop the PFET device 30 contains oxygen near a channel 60 positioned in the silicon containing substrate 10 underlying the PFET device 30. In one embodiment, during crystallizing, grain growth proceeds from inside the substrate 10 outward. Therefore, the crystallized layer 65 may have the same crystal orientation as the substrate 10 and is aligned to the substrate 10, although the same orientation is not required of all embodiments of the invention. In one embodiment, because crystallized layer 65 is formed under stress conditions, the intrinsic stress remains in the crystallized layer 65, even after the tensile strain layer 40 is removed. In one embodiment, crystallizing of the amorphous Si containing layer 35 is accomplished with a heat treatment, such as an rapid thermal process (RTP) spike anneal at about 1000 to about 1100° C. for about 1 second, or longer.

In one embodiment, during annealing to crystallize the amorphous Si-containing layer 35, oxygen is contained in the isolation region 13 and near the channel 60, or active region, of the PFET devices 30 by the portion of the tensile strain layer 40 that is positioned over the PFET devices 30. In one embodiment, the oxygen confined within the channel 60 of the PFET devices, shifts the threshold voltage of the PFET device 30 closer to the valence band of the Si-containing substrate 10. In one embodiment, the threshold voltage shift may range from about 50 mV to about 150 mV. The terms “confine” and “confined”, as used above to describe the oxygen that is present in the channel 60, means that the oxygen present in the isolation region 13 and near the channel 60 is retained from outdiffusing from the isolation region 13 and channel 60 of the pFET device 30 to an exterior of the semiconductor device by the portion of the tensile strain layer 40 that is positioned over the PFET devices 30. In one embodiment, the portion of the tensile strain layer 40 that is positioned over the PFET devices 30 confines oxygen from outdiffusion during anneal process steps, such as activation anneal.

In one embodiment, by shifting the threshold voltage of the PFET device closer to the valence band of the Si-containing substrate, the PFET device's 30 on and off voltage (also referred to as switching voltage) is lowered. In one embodiment, the threshold voltage of the PFET devices that are formed in accordance with the present invention may range from about 0.2 V to about 0.45 V. In another embodiment, the threshold voltage of the PFET devices 30 that are formed in accordance with the present invention may range from about 0.2 V to about 0.3 V. It is noted that the present invention provides a substantial improvement in threshold voltage as compared to prior PFET devices 30 of similar composition. Specifically, prior PFET devices 30 typically have a threshold voltage of approximately 0.6V. After completing the crystallization process, the tensile strain layer 40 is removed. In one embodiment, the tensile strain layer 40 is removed by wet etching.

Referring to FIG. 4, in a next process step silicide contacts 70 are formed atop the gate conductor of the PFET and NFET devices, as well as the source/drain regions of the PFET and NFET devices. Silicide formation typically requires depositing a refractory metal such as Pt, Ni or Ti onto the surface of a Si-containing material, such as the gate conductor and substrate. Following deposition, the structure is then subjected to an annealing step using conventional processes such as, but not limited to, rapid thermal annealing. During thermal annealing, the deposited metal reacts with Si forming a metal silicide.

In one embodiment, the present invention provides a method of forming a complementary metal oxide semiconductor (CMOS) device with a reduced number of process steps. More specifically, in one embodiment, as opposed to prior methods of forming a tensile strained NFET device with a tensile strain layer that has been deposited atop the NFET device and removed from the PFET device prior to recrystallization, the present invention maintains the tensile strain layer 40 atop the PFET device 30 during the crystallization anneal, hence capturing oxygen within the channel 60 of the PFET device 30 and shifting the threshold voltage of the PFET device 30 toward the valence band of the silicon containing substrate 10. Because, the present method does not remove the tensile strain layer 40 from the PFET device during crystallization, the present method does not include a mask and etch step prior to crystallization to remove the tensile strain layer 40 from the PFET device 30 as practiced in prior methods.

While the present invention has been particularly shown and described with respect to the preferred embodiments thereof, it will be understood by those skilled in the art that the foregoing and other changes in forms of details may be made without departing form the spirit and scope of the present invention. It is therefore intended that the present invention not be limited to the exact forms and details described and illustrated, but fall within the scope of the appended claims.

1. A method of manufacturing a semiconducting device comprising:
providing a silicon containing substrate having a first device region including at least one PFET device and a second device region including at least one NFET device, wherein the at least one NFET device includes an amorphous silicon containing region present in a portion of the silicon containing substrate in which a channel of the at least one NFET device is present;
depositing a tensile strain silicon nitride layer atop the at least one NFET device and the at least one PFET device, wherein the tensile strain silicon nitride layer induces a tensile strain in a channel of the at least one NFET device region;
annealing to crystallize the amorphous silicon containing region, wherein the tensile strain silicon nitride layer positioned atop the at least one PFET device confines oxygen within the channel positioned within the silicon containing substrate underlying the at least one PFET device, wherein the oxygen within the channel shifts a Fermi energy of the at least one PFET device towards a valence band of silicon of the silicon containing substrate; and
removing the tensile strain silicon nitride layer.

2. A method of manufacturing a semiconducting device comprising:
providing a silicon containing substrate having a first device region including at least one PFET device and a second device region including at least one NFET device, wherein the at least one NFET device includes an amorphous silicon containing region present in a portion of the silicon containing substrate in which a channel of the at least one NFET device is present;
forming a tensile strain layer atop the at least one NFET device and the at least one PFET device, wherein the tensile strain layer induces a tensile strain in a channel of the at least one NFET device region;
annealing to crystallize the amorphous silicon containing region to provide a crystallized region, wherein the tensile strain layer positioned atop the at least one PFET device confines oxygen in the channel positioned within the silicon containing substrate underlying the at least one PFET device, wherein the oxygen within the channel shifts a Fermi energy of the at least one PFET device towards a valence band of silicon of the silicon containing substrate; and
removing the tensile strain layer, wherein the tensile strain induced in the channel remains after the tensile strain layer is removed.
